(19) United States
(12) Patent Application Publication
(10) Pub. No.: US 2017/0312794 A1
(43) Pub. Date: Nov. 2, 2017

(54) APPARATUS AND METHOD FOR TREATING A SUBSTRATE

(71) Applicant: SEMES CO., LTD., Chungcheongnam-do (KR)

(72) Inventors: Jeong Yeong PARK, Chungcheongnam-do (KR); Kang Suk LEE, Chungcheongnam-do (KR); Heehwan KIM, Sejong-si (KR)

(21) Appl. No.: 15/491,491

(22) Filed: Apr. 19, 2017

(30) Foreign Application Priority Data
Apr. 29, 2016 (KR) 10-2016-0052994

(51) Int. Cl. B08B 3/10; B08B 3/08; B08B 3/04; H01L 21/67; H01L 21/02

(52) U.S. Cl. CPC B08B 3/106; H01L 21/67051; H01L 21/02101; B08B 3/041; B08B 3/08; B08B 2203/007

(57) ABSTRACT

Provided is a substrate treating apparatus comprising: a support unit for supporting the substrate; a discharge unit for discharging an organic solvent to the substrate supported on the support unit; and a solvent supply unit for supplying the organic solvent in a liquid state to the discharge unit at atmospheric pressure to a temperature higher than the boiling point of the organic solvent.

### CROSS-REFERENCE TO RELATED APPLICATIONS

A claim for priority under 35 U.S.C. §119 is made to Korean Patent Application No. 10-2016-0052994 filed on Apr. 29, 2016 in the Korean Intellectual Property Office, the entire contents of which are hereby incorporated by reference.

### BACKGROUND OF THE INVENTION

This disclosure relates to an apparatus and method for treating a substrate.

Conventionally, in a method for manufacturing a semiconductor device, a variety of processes such as photo process, an etching process, an ion implantation process and a deposition process are performed on a substrate like a silicon wafer. And when performing each process a variety of substances like a particle, an organic containment, a metal impurity, and so on are generated. These substances causes defect in the substrate and affects performance and yield of the semiconductor device, thereby a cleaning process for removing these substances is required.

Cleaning process includes a chemical treating process for removing contaminants in the substrate, a wet cleaning process for removing chemical remained in the substrate with pure water, and a drying process for drying pure water remaining in the substrate by providing a dry fluid.

In the past, the drying process was performed by supplying nitrogen gas onto the substrate where pure water remained. However, as the line width of the pattern formed on the substrate becomes narrower and the aspect ratio becomes larger, the removal of pure water between the patterns is not performed well. For this purpose, pure water is replaced on a substrate with an organic solvent such as isopropyl alcohol, which has a higher volatility and relatively lower surface tension than pure water, and then the substrate is dried by supplying heated nitrogen gas.

However, such a drying method causes a pattern collapse such as a leaning phenomenon in a semiconductor device having a fine circuit pattern with a line width of 30 nm or less even if an organic solvent is used. This is due to the surface tension of the organic solvent. The larger the surface tension, the greater the leaning. Thus, in recent years, it is more important to reduce the surface tension of the process fluid as the pattern on the substrate becomes finer.

FIG. 1 is a graph showing the tension of the surface tension of isopropyl alcohol by temperature. Referring to FIG. 1, as the temperature of the liquid isopropyl alcohol rises, the surface tension decreases. Therefore, it is preferable to supply isopropyl alcohol to the substrate in a state where the isopropyl alcohol is heated to as high a temperature as possible.

On the other hand, conventionally, isopropyl alcohol was supplied onto the substrate at atmospheric pressure. Also, the isopropyl alcohol supplied to substitute the pure water remaining on the substrate should be in a liquid state. Therefore, the temperature at which isopropyl alcohol was supplied as a liquid phase to the substrate was lower than the boiling point of isopropyl alcohol at atmospheric pressure.

That is, when isopropyl alcohol is heated to lower the surface tension of isopropyl alcohol, boiling point of isopropyl alcohol at atmospheric pressure is formed at about 80° C., so when it is heated to a higher temperature, isopropyl alcohol is vaporized. Therefore, it is impossible to supply isopropyl alcohol in a liquid state, so that it cannot be heated to a boiling point (about 80° C.) at atmospheric pressure. As described above, there is a limitation in lowering the surface tension of liquid isopropyl alcohol supplied on the substrate. As a result, it has been difficult to prevent the leaning phenomenon on the substrate pattern.

### SUMMARY OF THE INVENTION

An embodiment provides a substrate treating apparatus and method therein which may treat a substrate with an with an organic solvent having a surface tension lower than that of a conventional one by heating the organic solvent at a boiling point or more at atmospheric pressure.

An embodiment provides a substrate treating apparatus and method therein which may prevent damage to the substrate pattern.

The objects of the inventive concept are not limited to the above descriptions. Other objects thereof will be understandable by those skilled in the art from the following descriptions.

Embodiments of the inventive concept provide a substrate treating apparatus.

A substrate treating apparatus comprises: a support unit for supporting the substrate; a discharge unit for discharging an organic solvent onto the substrate supported on the support unit; and a solvent supply unit for supplying the organic solvent in a liquid state to the discharge unit at atmospheric pressure to a temperature higher than the boiling point of the organic solvent.

In example embodiments, the solvent supply unit comprises: a tank including an inner space in which the organic solvent is filled; a heating member for heating the organic solvent in the tank; a pressing member for controlling a pressure of the inner space; and a connection pipe for connecting the tank and the discharge unit.

In example embodiments, the solvent supply unit further comprises a controller. The controller controls the heating member so that the temperature of the organic solvent is heated to a target temperature higher than the boiling point of the organic solvent at atmospheric pressure, and controls the pressing member so that the organic solvent is maintained in a liquid state at the target temperature.

In example embodiments, the pressing member comprises a gas supply pipe for supplying gas into the inner space.

In example embodiments, the tank comprises a circulation line for circulating the liquid contained therein, wherein the heating member is provided in the circulation line.

In example embodiments, the organic solvent is isopropyl alcohol.

In example embodiments, the gas is an inert gas.

Embodiments of the inventive concept provide a method for treating a substrate.

In example embodiments, the method comprises treating the substrate by supplying an organic solvent in a liquid state to the substrate, wherein the organic solvent is supplied at a temperature higher than the boiling point of the organic solvent at atmospheric pressure.

In example embodiments, the method comprises: an organic solvent supplying step for supplying the organic solvent to an inner space of the tank; a pressing step for raising a pressure of the inner space; and a heating step for heating the organic solvent contained in the inner space to a target temperature higher than a boiling point of the organic solvent at atmospheric pressure, wherein in the heating step, the organic solvent contained in the inner space at the target temperature is heated to maintain the liquid phase.

In example embodiments, in the organic solvent supplying step, the organic solvent is supplied to a part of the inner space, and in the pressing step, the gas is supplied to the remainder of the inner space such that the pressure of the inner space is higher than the atmospheric pressure.

In example embodiments, in the pressing step, the organic solvent is supplied to the inner space, and the pressure of the inner space is maintained to be higher than the atmospheric pressure.

In example embodiments, the gas is an inert gas.

In example embodiments, the organic solvent is isopropyl alcohol.

In example embodiments, the treating the substrate is a process of replacing the liquid on the substrate with the organic solvent.

In example embodiments, the liquid on the substrate is pure water.

According to an embodiment, the substrate may be treated an organic solvent having a lower surface tension than that of the conventional one by heating the organic solvent at a boiling point or more at nor atmospheric mal pressure.

According to an embodiment, damage to the substrate pattern may be prevented.

The objects of the inventive concept are not limited to the above mentioned effects. Other objects thereof will be understandable by those skilled in the art from the following descriptions and the present application.

### BRIEF DESCRIPTION OF THE DRAWINGS

FIG. 1 is a graph showing the tension of the surface tension of isopropyl alcohol by temperature.

FIG. 2 is a plan view of schematically illustrating a substrate treating apparatus.

FIG. 3 is a drawing of schematically illustrating a substrate treating apparatus according to an embodiment.

FIG. 4 is a drawing of a solvent supply unit of the substrate treating apparatus of FIG. 3.

FIGS. 5 to 8 are drawings sequentially illustrating a substrate treating process according to an embodiment.

FIG. 9 is a flowchart showing a procedure of a substrate treating process according to an embodiment.

FIG. 10 is a drawing showing a modification example in which the inside of the tank is pressurized.

### DETAILED DESCRIPTION

Various example embodiments will be described more fully hereinafter with reference to the accompanying drawings, in which some example embodiments are shown. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Therefore, features of the drawings are exaggerated to emphasize definite explanation.

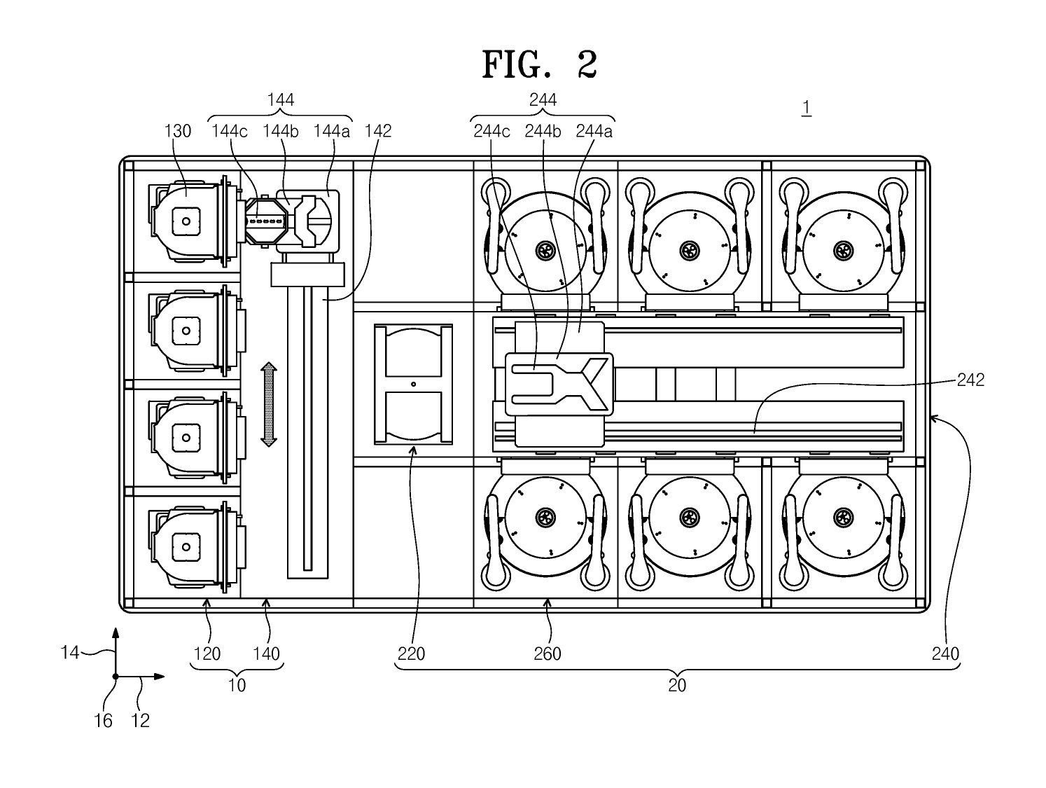

Hereinafter, an example of the present invention will be described in detail with reference to FIGS. 2 to 9.

FIG. 2 is a plan view of schematically illustrating a substrate treating apparatus 1. Referring to FIG. 2, the substrate treating apparatus 1 comprises an index module 100 and a process treating module 200. The index module 100 includes a load port 120 and a transfer frame 140. The load port 120, the transfer frame 140, and the process treating module 200 are sequentially arranged in a row. Hereinafter, a direction where the load port 120, the transfer frame 140, and the process treating module 200 are arranged is referred to as a first direction 12. And a direction perpendicular to the first direction 12 is referred to as a second direction 14, when view from a top side, and a direction perpendicular to a plane including the first direction 12 and the second direction 14 is referred to as a third direction 16.

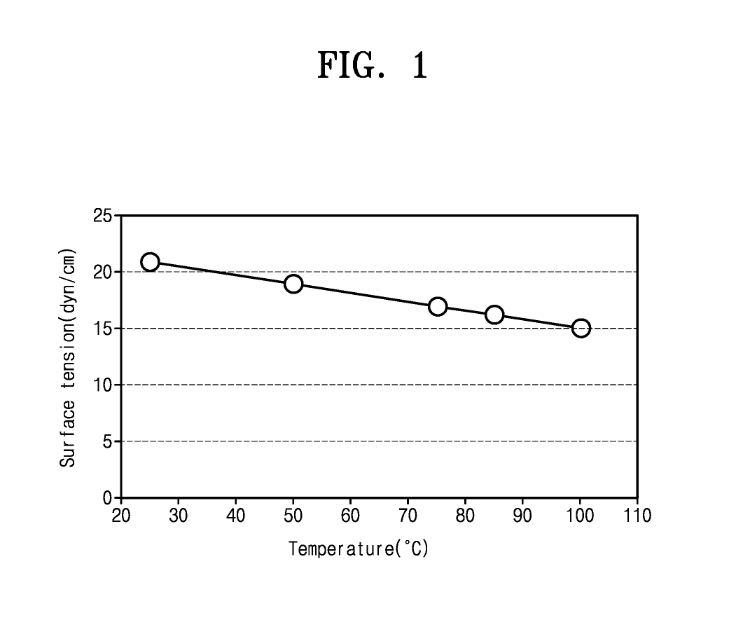

A carrier 130 where a substrate W is stored is seated on the load port 120. The load port 120 is provided as a plurality of numbers and they are arranged in a row along the second direction 14. In the FIG. 1, it described that four load ports 120 are provided. However, the number of load ports 120 may be increased or decreased depending on a requirement like process efficiency and a footprint of the process treating module 200. In the carrier 130, a plurality of slots (not described) are provided to support an edge of the substrate W. A plurality of slots are provided along the third direction 16 and a plurality of substrates W is placed inside the carrier vertically stacked to each other along the third direction 16. A front opening unified pod (FOUP) may be used as the carrier 130.

The process treating module 200 comprises a buffer unit 220, a transfer chamber 240, and a process chamber 260. The transfer chamber 240 is provided such that the lengthwise direction thereof is parallel with the first direction 12. The process chambers 260 are provided in one side and the other side of the transfer chamber 240 along the second direction 14, respectively. The process chambers 250 are provided symmetrically in one and the other sides of the transfer chamber 240. Some of the process chambers 260 are placed along the lengthwise direction of the transfer chamber 240. Also, some of the process chambers 260 are placed vertically stacked to each other. That is, in one side of the transfer chamber 240, the process chambers 260 may be arranged in A×B (A and B are natural number of 1 or above) array. Herein, A is the number of the process chambers 250 which are provided along the first direction 12, and B is the number of process chambers 260 which are provided along the third direction 16. When four or six process chambers 260 are provided on one side of the transfer chamber 240, the process chambers 260 may be arranged in 2×2 or 3×2 arrays. The number of the process chamber 260 may be increased or decreased. Unlike described above, the process chamber 260 may be provided only on one side of the transfer chamber 240. Also, unlike described above, the process chamber 260 may be provided as a single layer at both sides of the transfer chamber 240.

The buffer unit 220 is arranged between the transfer frame 140 and the transfer chamber 240. The buffer unit 220 provides a space for the substrate W to stay temporarily before transferring the substrate W between the transfer chamber 240 and the transfer frame 140. The slot (not described) where the substrate places is provided inside of the buffer unit 220, and the slots (not described) are provided with a plurality of numbers spaced apart from each other along the third direction 16. One side of the buffer unit 220 facing the transfer frame 140, and the other side of the buffer unit 220 facing the transfer chamber 240 are opened.

The transfer frame 140 transfers the substrate W between the buffer unit 220 and the carrier 130 seated on the load port 120. In the transfer frame 140, an index rail 142 and an index robot 144 are provided. The index rail 142 is provided such that the lengthwise direction is parallel to the second direction 14. The index robot 144 is installed on the index rail 142, and move linearly along the index rail 142 to the second direction 14. The index robot 144 comprises a base 144a, a body 144b, and an index arm 144c. The base 133a is installed movably along the index rail 142. The body 144b is coupled to the base 144a. The body 144b is provided movably along the third direction 16 on the base 144a. Also, the body 144b is provided rotatable on the base 144a. The index arm 144c is coupled to the body 144b, and is provided to move front and back to the body 144b. The index arm 144c is provided with a plurality of numbers and they are driven independently. The index arms 144c are arranged vertically, i.e., spaced apart from each other along the third direction 16. Some of the index arms 144c may be used when transferring the substrate W from the process treating module 200 to the carrier 130, and some may be used when transferring the substrate W from the carrier 130 to the process treating module 200. In this way, during the index robot 144 carries in or carries out the substrate W, particles that have come from a substrate before treating process may be prevented from adhering to a substrate after treating process.

The transfer chamber 240 transfers the substrate W between process chambers 260 and the buffer unit 220 and between the process chambers 260. A guide rail 242 and a main robot 244 are provided in the transfer chamber 240. The guide rail 242 is places such that the lengthwise direction is parallel with the first direction 12. The main robot 244 is installed on the guide rail 242, and moves linearly along the first direction 12 on the guide rail 242. The main robot 244 comprises a base 244a, a body 244b, and a main arm 244c. The base 244a is installed movably along the guide rail 242. The body 244b is coupled to the base 244a. The body 244b is provided movably along the third direction 16 on the base 244a. Also, the body 244b is provided rotatable on the base 244a. The main arm 244c is coupled to the body 244b, and is provided to move front and back to the body 244b. The main arm 244c is provided with a plurality of numbers and they are provided to drive separately. The main arms 244c are arranged vertically, i.e., spaced apart from each other along the third direction 16. The main arm 244c used when transferring the substrate W from the buffer unit 220 to the process chamber 260, and the main arm 244c used when transferring the substrate W from the process chamber 260 to the buffer unit 220 may be different.

In the process chamber 260, a substrate treating apparatus 300 which performs a cleaning process to the substrate W is provided. The substrate treating apparatus 300 provided in each process chambers 240 may have different structure based on kinds of cleaning process. The substrate treating apparatus 300 provided in each process chambers 240 may have the same structure. In one embodiment, the process chambers 260 may be divided into a plurality of groups, and the substrate treating apparatus 300 provided in the same group of the process chamber 260 may have the same structure, and the substrate treating apparatus 300 provided in different group of the process chamber 260 may have different structure. For example, when the process chamber 260 is divided into two groups, a first group of the process chambers 260 are provided in one side of the transfer chamber 240, and a second group of the process chambers 260 are provided in the other side of the transfer chamber 240. In one embodiment, a first group of the process chamber 260 and a second group of the process chambers 260 are stacked in this order both in one side and the other side of the transfer chamber 240. The process chambers 260 may be divided into several groups depending on a kinds of chemicals or kinds of cleaning process used.

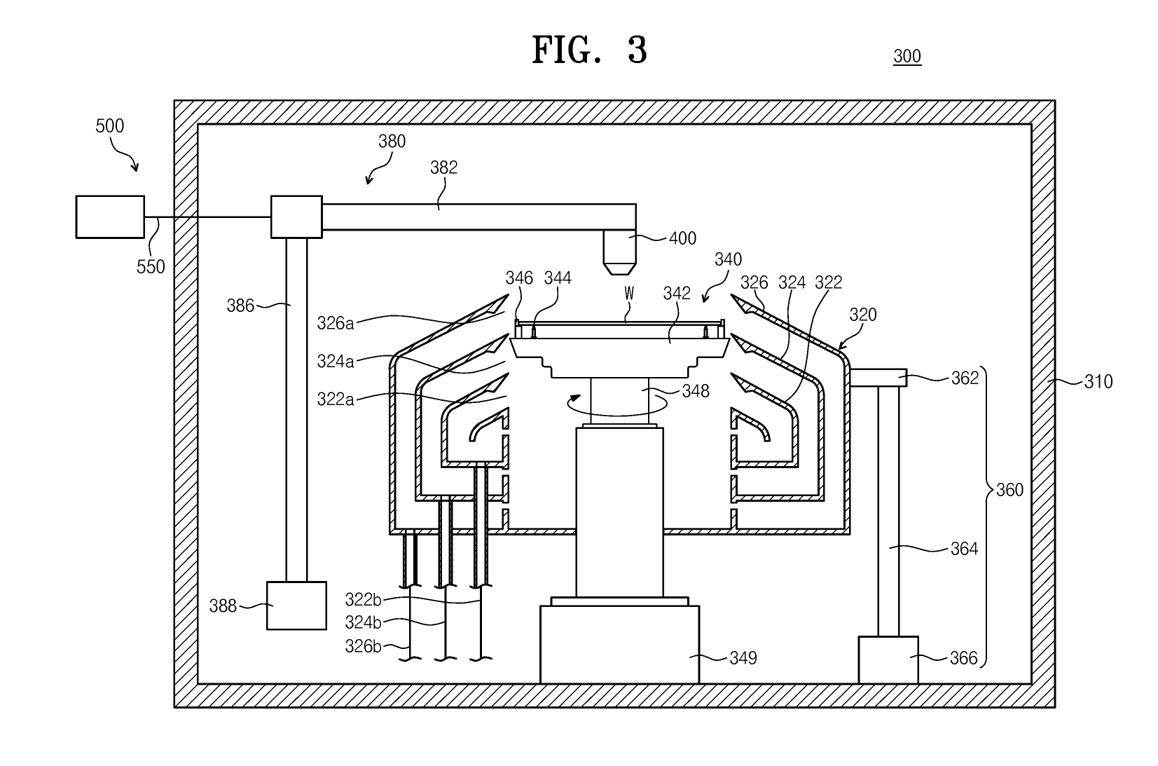

An example of the substrate treating apparatus 300 for treating the substrate W will be described below. FIG. 3 is a view showing an example of the substrate treating apparatus 300.

Referring to FIG. 3, the substrate treating apparatus 300 comprises a chamber 310, a cup 320, a support unit 340, an elevator unit 360, a discharge unit 380, and a solvent supply unit 400.

The chamber 310 provides a space in its inner side. The cup 320 is placed inside of the chamber 310. The cup 320 provides a treating space where a substrate treating process is performed and has open upper side. The cup 320 comprises an inner collecting container 322, a middle collecting container 324, and an outer collecting container 326. Each collecting containers 322, 324, 326 collects chemical that are different from each other among treatment liquids used in a process. The inner collecting container 322 is provided as a ring shape surrounding the supporting unit 330. The middle collecting container 324 is provided as a ring shape surrounding the inner collecting container 322. The outer collecting container 326 is provided as a ring shape surrounding the middle collecting container 324. An inner space 322a of the inner collecting container 322, an interspace 324a between the inner collecting container 322 and the middle collecting container 324, and an interspace 326a between the middle collecting container 324 and the outer collecting container 326 may function as a inlet where the chemical flows into the inner collecting container 322, the middle collecting container 324, and the outer collecting container 326, respectively. In the collecting containers 322, 324, 326, collecting lines 322b, 324b, 326b are connected which are extended vertically downward to the bottom, respectively. Collecting lines 322b, 324b, 326b emit the chemical inflow through the collecting containers 322, 324, 326, respectively. The emitted chemical may be reused through a treatment liquid regeneration system (not described) of outside.

The support unit 340 is placed inside of the cup 320. The support unit 340 supports the substrate W and rotates the substrate W during the substrate treating process. The support unit 340 comprises a spin head 342, a supporting pin 344, a chuck pin 346, a supporting shaft 348, and a motor 349. The spin head 342 has an upper surface usually provided as a circular form, when viewed from a top side. At the bottom of the spin head 342 the supporting shaft 348 rotatable by a motor 349 is fixedly connected. When the motor 348 rotates, the spin head 342 rotates. The spin head 342 includes a supporting pin 344 and a chuck pin 346 to support the substrate. The supporting pin 344 is provided with a plurality of numbers. The plurality of supporting pins 344 are spaced apart from each other on edge of the upper surface of the spin head 342 and protrude upward from the spin head 342. The supporting pins 344 are generally arranged to have a ring shape. The supporting pin 344 supports the back side of the substrate W as to be spaced apart from the upper surface of the spin head 342. The chuck pin 346 is provided as a plurality number. The chuck pin 346 is arranged further apart from a center of the spin head 342 than the supporting pin 344. The chuck pin 346 is provided as to protrude upward from the spin head 342. The chuck pin 346 supports lateral part (side) of the substrate W such that the substrate W does not deviate from a right position to a side direction when the support unit 340 is rotating. The chuck pin 346 is provided to move linearly between standby position and supporting position along a radius direction of the spin head 342. The standby position is further apart from a center of the spin head 342 than the supporting position. When loading and unloading the substrate W on and from the support unit 340, and when processing the substrate W, the chuck pin 346 is placed on the supporting position. The chuck pin 346 on the supporting position is contacted with the lateral part of the substrate.

The elevator unit 360 moves the cup 320 linearly to up and down direction. The elevator unit 360 may move a plurality of the collecting containers 322, 324, 326 of the cup 320. Although, it is not described, the elevator unit 360 may move the collecting containers 322, 324, 326, individually. As the cup 320 moves up and down a height of the cup 320 relative to the support unit 340 is changed. The elevator unit 360 comprises a bracket 362, a moving shaft 364, and a driver 366. The bracket 362 is fixedly installed on outer wall of the cup 320. To the bracket 362, the moving shaft 364 moving up and down direction by the driver 366 is fixedly coupled. When the substrate W is placed on the support unit 340or when lifted from the support unit 340, the cup 320 descends such that the support unit 340 protrudes from the cup 320. Also, during processing, the height of the cup 320 is controlled such that the treatment liquid flows into the predetermined collecting container 360 depending on a kind of chemical supplied in the substrate W. In an example, when treating the substrate W with the first chemical, the substrate W is placed on a height corresponding to the inner space 322a of the inner collecting container 322. Also, when treating the substrate W with the second chemical and the third chemical, the substrate W is placed on a height corresponding to the interspace 324a between the inner collecting container 322 and the middle collecting container 324, and the interspace 326a between the middle collecting container 324 and the outer collecting container 326, respectively. Different from the above, the elevator unit 360 may move the support unit 340 up and down direction instead of the cup 320.

The discharge unit 380 supplies the chemical to the substrate W. The chemical may be a detergent, a rinse agent or an organic solvent. As the detergent, a hydrogen peroxide (H2O2) solution or a hydrogen peroxide solution mixed with ammonia (NH4OH), hydrochloric acid (HCl ) or sulfuric acid (H2SO4) or a hydrofluoric acid solution may be used. The rinse agent rinses the detergent. The rinse agent may be pure water. After the rinsing agent is discharged, the organic solvent can be discharged. The organic solvent replaces the liquid rinsing agent. In one example, the organic solvent replaces pure water. As the organic solvent, isopropyl alcohol, or a solution or gas of ethyl glycol, l-propanol, tetra hydraulic franc, 4-hydroxyl, 4-methyl, 2-entanone, 1-butanol, 2-butanol, methanol, ethanol, n-propyl alcohol, and dimethylethe may be used.

The discharge unit 380 may be rotatable. One or a plurality of the discharge units 380 may be provided. The discharge unit 380 comprises a nozzle support 382, a supporter 386, a driver 388, and a nozzle 400. The supporter 386 is provided such that its lengthwise direction is parallel with the third direction 16, and the driver 388 is coupled at the bottom of the supporter 386. The nozzle support 382 is perpendicularly coupled to one end of the supporter 386 which is opposite the other end of the supporter 386 to which the driver 388 is coupled. The nozzle 400 is installed at the bottom of an end of the nozzle support 382. The nozzle 400 is moved to a processing position and a standby position by the driver 388. The processing position is where the nozzle 400 is located vertically above the cup 320, and the standby position is where the nozzle 400 is not vertically above the cup 320.

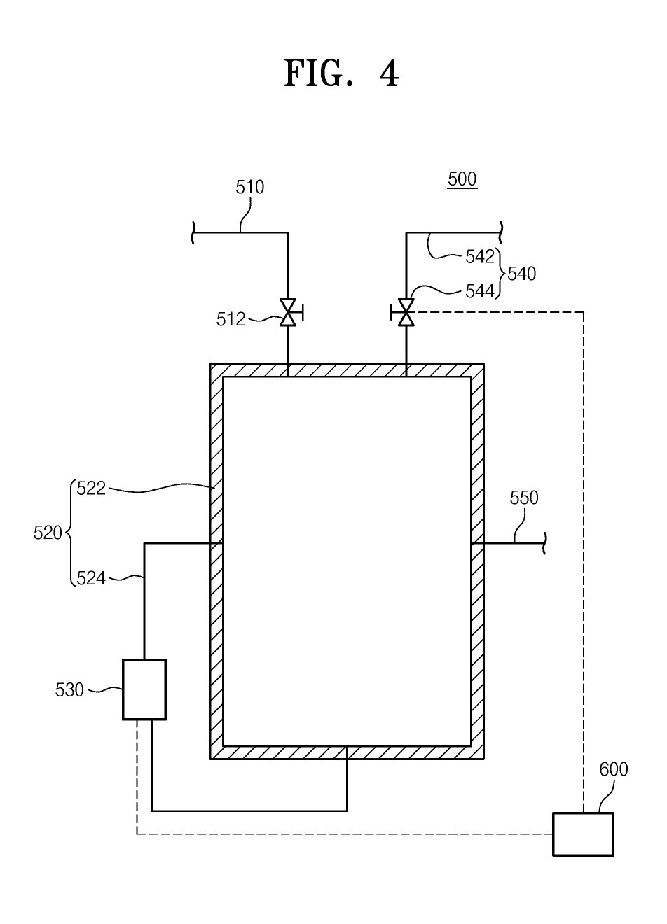

FIG. 4 is a drawing of a solvent supply unit of the substrate treating apparatus of FIG. 3.

A solvent supply unit 500 supplies an organic solvent in a liquid state to the discharge unit 380. The solvent supply unit 500 comprises a central supply pipe 510, a tank 520, a heating member 530, a pressing member 540, a connection pipe 550, and a controller 600.

The central supply pipe 510 supplies organic solvent to the tank 520 from a central supply unit (not shown). The pressure at which the organic solvent is supplied may be greater than the atmospheric pressure P1. For example, the supply pressure of the organic solvent may be 7 atm to 8 atm. The central supply pipe 510 may be provided with a valve 512. The valve 512 controls the organic solvent supplied into the tank 520. For example, when organic solvent is supplied to a part of the inner space of the tank 520, the valve 512 may be closed. Alternatively, the valve 512 may not be closed until organic solvent is supplied to all of the inner space of the tank 520.

The tank 520 includes a housing 522 and a circulation line 524. The organic solvent is contained in the inner space of the tank 520. The circulation line 524 is connected to the tank 520 at one end and the other end to circulate the organic solvent in the tank 520.

The heating member 530 heats the organic solvent contained in the tank 520. The heating member 530 may be provided on the circulation line 524. The heating member 530 heats the liquid organic solvent circulating along the circulation line 524. The heating member 530 heats the organic solvent to a temperature higher than the boiling point Tb of the organic solvent at the atmospheric pressure P1. In one example, if the organic solvent is isopropyl alcohol, it is heated to a target temperature Tt higher than about 80° C, which is the boiling point Tb of isopropyl alcohol at atmospheric pressure P1. As an example, the target temperature Tt may be 85° C. The target temperature Tt is a temperature at which the organic solvent can maintain the liquid phase without being vaporized. The heating member 530 heats the organic solvent only within such a target temperature Tt range. That is, the heating member 530 heats only within a temperature range in which the organic solvent does not vaporize. The target temperature Tt is set in consideration of the pressure inner space of the tank 520. In this regard, the pressing member 540 will be described later.

The pressure member 540 regulates the pressure inner space of the tank 520. The pressure member 540 raises the pressure inner space of the tank 520. The pressing member 540 includes a gas supply pipe 542. The gas supply pipe 542 supplies gas to the inner space of the tank 520. The gas supply pipe 542 may be provided with a gas valve 544 for regulating gas supply. The pressure at which the gas is supplied may be provided to be larger than the atmospheric pressure P1. For stability of the apparatus, the gas may be a gas which is not reactive with the organic solvent. In one example, the gas may be an inert gas. The gas may be nitrogen gas.

In an example, the organic solvent supplied from the central supply pipe 510 fills a part of the inner space of the tank 520 and then supplied to the inner space of the tank 520 through the gas supply pipe 542. As the gas fills the inner space of the tank 520, the pressure in the inner space of the tank 520 rises. The raised internal pressure is maintained at a pressure P2higher than the atmospheric pressure P1. For example, it can be maintained at 1.3 to 1.5 atmospheres.

The connection pipe 550 connects the tank 520 and the discharge unit 380. The organic solvent in the inner space of the tank 520 moves to the discharge unit 380 through the connection pipe 550. A liquid organic solvent heated to the target temperature (Tt) flows in the connection pipe (550). The transferred organic solvent is discharged onto the substrate through the discharge unit 380.

The controller 600 controls the pressing member 540 and the heating member 530. The controller 600 controls the heating member 530 such that the temperature of the organic solvent is heated to the target temperature Tt higher than the boiling point Tb at the atmospheric pressure P1, and the pressure member 540 is controlled so that the organic solvent is maintained in the liquid state at the target temperature Tt. That is, the controller 600 sets the target temperature Tt so that the organic solvent can be maintained in the liquid state without being vaporized, considering the pressure inside the tank 520 and the boiling point of the organic solvent. Then, the organic solvent is heated within the target temperature Tt.

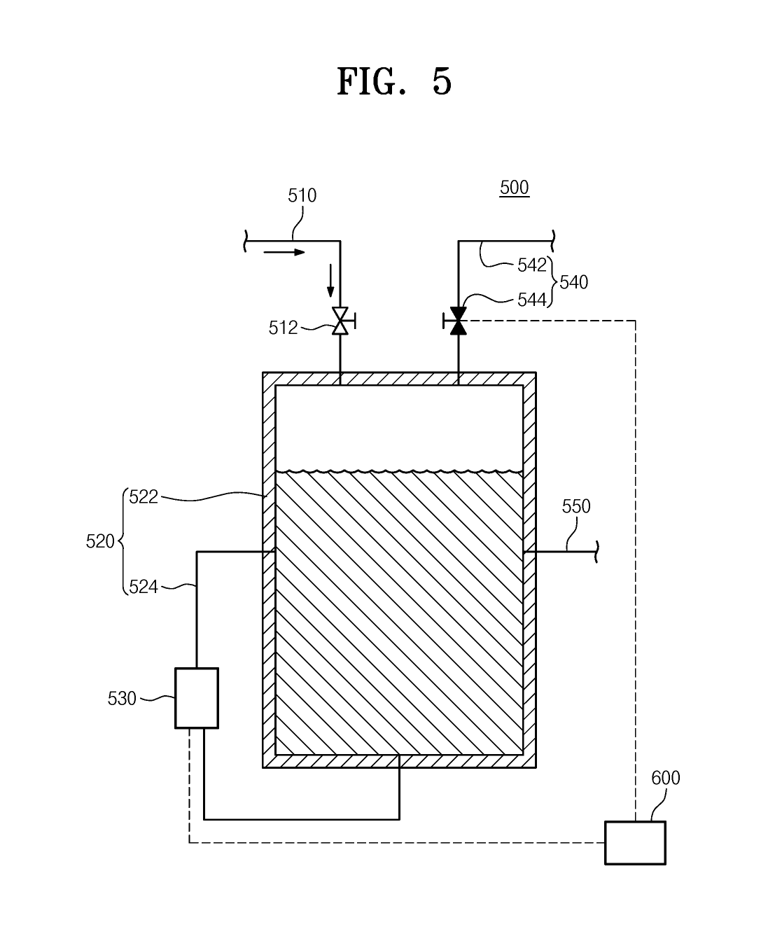

Hereinafter, a substrate treating process according to an embodiment will be described with reference to FIGS. 5 to 9. The arrow indicates the flow of the organic solvent.

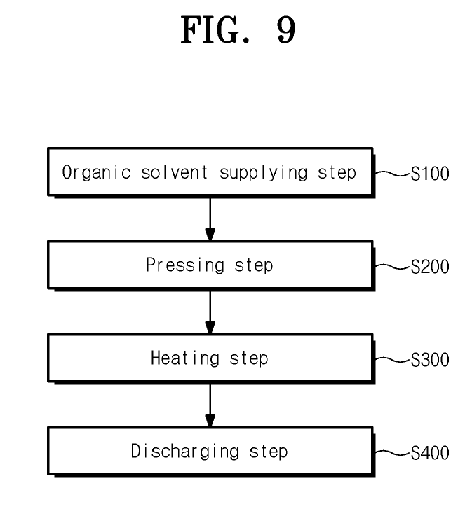

The substrate treating method according to an embodiment comprises an organic solvent supplying step S100, a pressing step S200, a heating step S300, and a discharging step S400 (see FIG. 9).

Referring to FIG. 5, in the organic solvent supplying step S100, the organic solvent is supplied from the central supply device to the inner space of the tank 520 through the central supply pipe 510. The supplied organic solvent may fill only a part of the inner space of the tank 520.

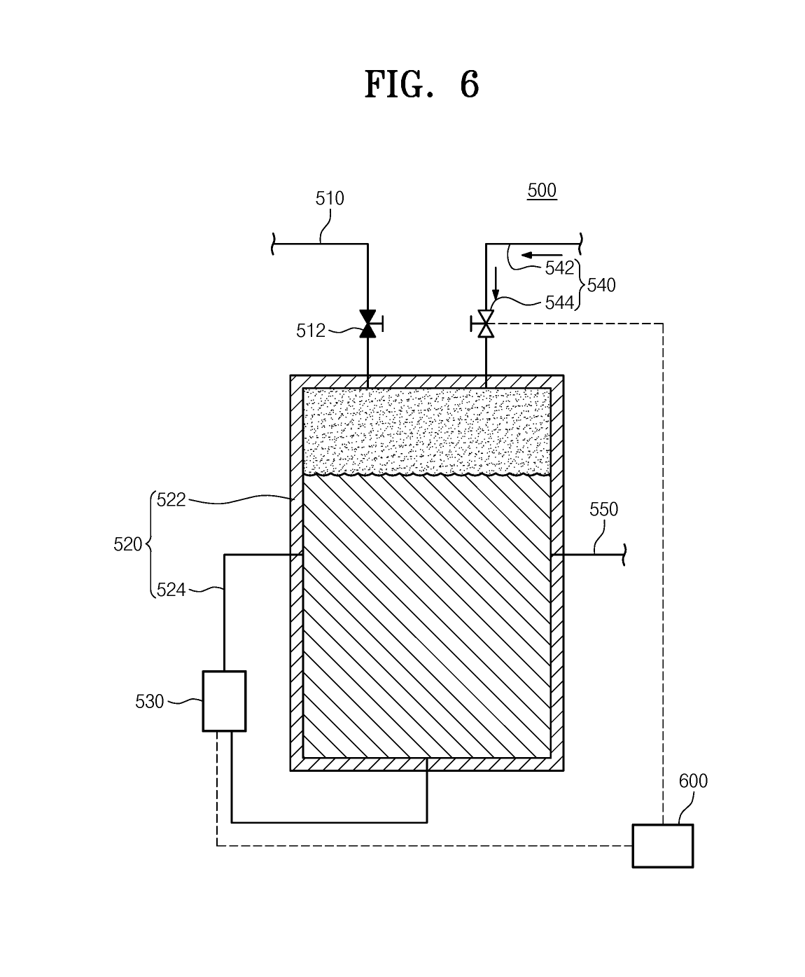

Referring to FIG. 6, in the pressing step S200, a gas is supplied to the inner space of the tank 520 through the gas supply pipe 542. After the predetermined amount of the organic solvent is filled from the central supply pipe 510, the valve 512 is closed and the gas is supplied through the gas supply pipe 542. The gas may be an inert gas which is not reactive with the organic solvent. The gas may be nitrogen gas. The residual pressure of the inner space of the tank 520 is filled with the gas so that the pressure P2 of the inner space is higher than the atmospheric pressure P1. As a result, the boiling point of the organic solvent rises above the boiling point Tb at the atmospheric pressure P1. Therefore, even if heated to a temperature higher than the boiling point Tb at the atmospheric pressure P1, the liquid phase can be maintained.

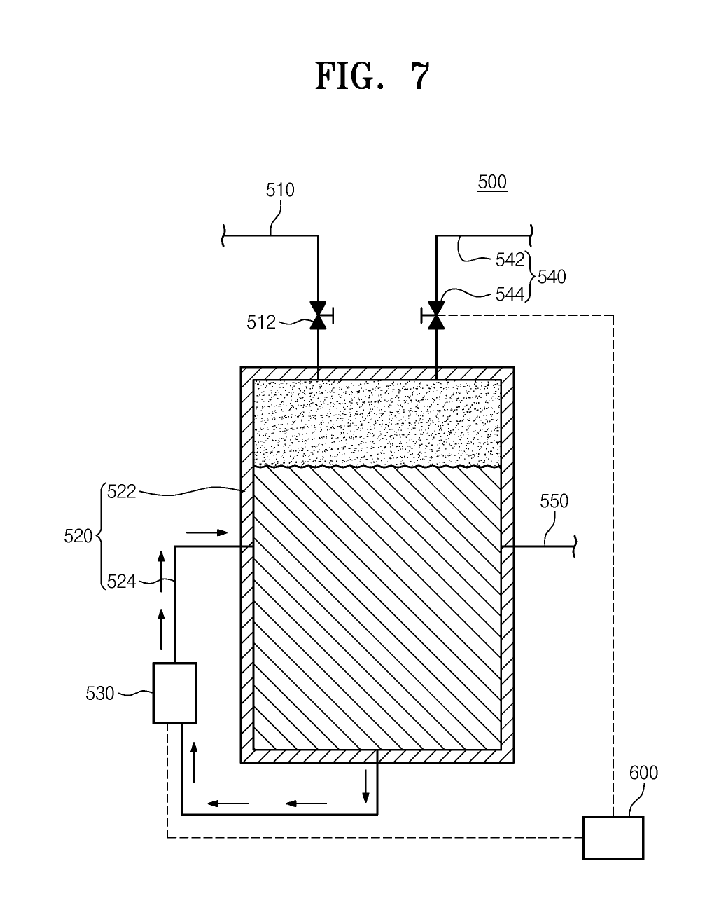

Referring to FIG. 7, in the heating step S300, an organic solvent of inner space of the tank 520 is heated. And it heats the organic solvent and circulates through the circulation line 524 while the pressure is higher than the atmospheric pressure P1. The organic solvent is heated via a heating member 530 such as a heater provided in the circulation line 524. The target temperature Tt to be heated is a temperature higher than the boiling point Tb at the atmospheric pressure P1 of the organic solvent. However, considering the boiling point of the organic solvent according to the internal pressure of the tank 520, which is higher than the atmospheric pressure P1, the target temperature Tt at which the liquid organic solvent is not vaporized is set and the object is heated within the target temperature Tt.

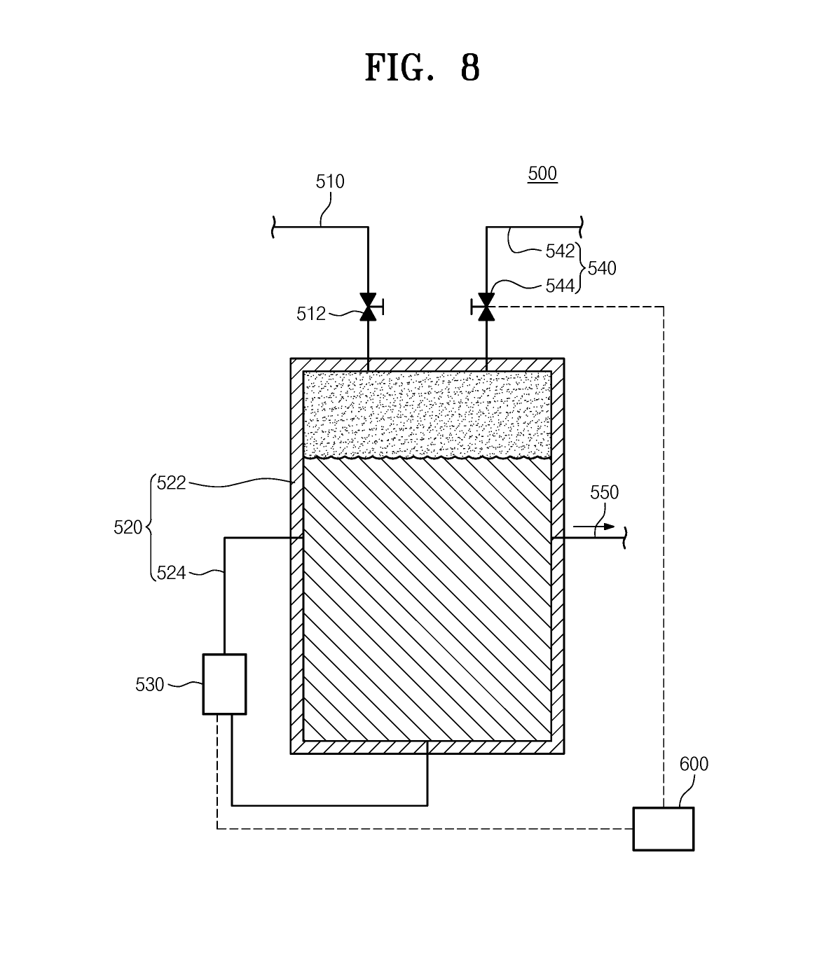

Referring to FIG. 8, in the discharging step S400, the liquid organic solvent heated to the target temperature Tt is supplied to the substrate by the injection unit. On the substrate, a rinsing agent such as pure water remains on the substrate. The liquid organic solvent replaces pure water. The substituted organic solvent is dried through a subsequent treatment process. Since the discharged liquid organic solvent has a higher temperature than the conventional one, the surface tension is lower than the conventional one. Thus, the substrate can be cleaned with minimal damage to the substrate pattern, such as leaning.

In the above embodiment, the pressure of the inner space of the tank is raised by filling organic solvent in a part of the inner space of the tank and supplying gas to the remaining part. However, it is limited therein, and any method may be used as long as it increases the pressure of the space inside the tank.

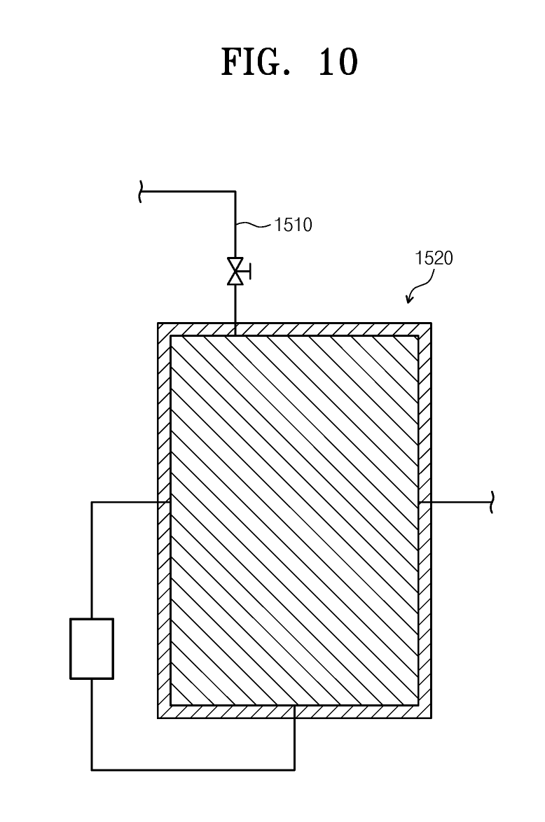

For example, referring to FIG. 10, the organic solvent may be supplied to the inner space of a tank 1520 by supplying the organic solvent through a central supply pipe 1510 at a pressure P2higher than the atmospheric pressure P1. At this time, the gas supply pipe may be omitted. In this manner, the pressure of the space inside the tank 1520 can be maintained at the pressure P2higher than the atmospheric pressure P1.

Specifically, in the pressing step S200, the organic solvent is continuously supplied from the central supply pipe 1510 without interruption so that the organic solvent is filled in the inner space of the tank 1520. The valve may be omitted. At this time, the space inside the tank 1520 is set to a pressure higher than the atmospheric pressure P1. For example, the pressure P2 to which the organic solvent is supplied can be transferred into the tank 1520 as it is. That is, the supply pressure inside the tank 1520 reaches the pressure P2 at which the organic solvent is supplied.

In the above embodiment, the heating member is provided in the circulation line, but it is not limited therein, any method may be used as long as it is a method for heating the organic solvent in the tank. Also, the circulation line may be omitted.

Foregoing embodiments are examples of the present invention. Further, the above contents merely illustrate and describe preferred embodiments and embodiments may include various combinations, changes, and environments. That is, it will be appreciated by those skilled in the art that substitutions, modifications and changes may be made in these embodiments without departing from the principles and spirit, the scope of which is defined in the appended claims and their equivalents. Further, it is not intended that the scope of this application be limited to these specific embodiments or to their specific features or benefits. Rather, it is intended that the scope of this application be limited solely to the claims which now follow and to their equivalents.

What is claimed is:

1. A substrate treating apparatus comprising:
a support unit for supporting the substrate;
a discharge unit for discharging an organic solvent onto the substrate supported on the support unit; and
a solvent supply unit for supplying the organic solvent in a liquid state to the discharge unit at atmospheric pressure to a temperature higher than the boiling point of the organic solvent.

2. The apparatus of claim 1, the solvent supply unit comprises:
a tank including an inner space in which the organic solvent is filled;
a heating member for heating the organic solvent in the tank;
a pressing member for controlling a pressure of the inner space; and
a connection pipe for connecting the tank and the discharge unit.

3. The apparatus of claim 2, wherein the solvent supply unit further comprises a controller and wherein the controller controls the heating member so that the temperature of the organic solvent is heated to a target temperature higher than the boiling point of the organic solvent at atmospheric pressure, and controls the pressing member so that the organic solvent is maintained in a liquid state at the target temperature.

4. The apparatus of claim 3, wherein the pressing member comprises a gas supply pipe for supplying gas into the inner space.

5. The apparatus of claim 4, wherein the tank comprises a circulation line for circulating the liquid contained therein, wherein the heating member is provided in the circulation line.

6. The apparatus of claim 1, wherein the organic solvent is isopropyl alcohol.

7. The apparatus of claim 6, wherein the gas is an inert gas.

8. A method for method for treating a substrate comprising:
treating the substrate by supplying an organic solvent in a liquid state to the substrate, wherein the organic solvent is supplied at a temperature higher than the boiling point of the organic solvent at atmospheric pressure.

9. The method of claim 8, further comprising:
an organic solvent supplying step for supplying the organic solvent to an inner space of the tank;
a pressing step for raising a pressure of the inner space; and
a heating step for heating the organic solvent contained in the inner space to a target temperature higher than a boiling point of the organic solvent at atmospheric pressure,
wherein in the heating step, the organic solvent contained in the inner space at the target temperature is heated to maintain the liquid phase.

10. The method of claim 9, wherein in the organic solvent supplying step, the organic solvent is supplied to a part of the inner space, and wherein in the pressing step, the gas is supplied to the remainder of the inner space such that the pressure of the inner space is higher than the atmospheric pressure.

11. The method of claim 10, wherein the gas is an inert gas.

12. The method of claim 9, wherein in the pressing step, the organic solvent is supplied to the inner space, and the pressure of the inner space reaches the supply pressure of the organic solvent higher than the atmospheric pressure.

13. The method of claim 12, wherein in the pressing step, the organic solvent is continuously supplied to keep the organic solvent filled in the entire inner space of the tank.

14. The method of claim 8, wherein the organic solvent is isopropyl alcohol.

15. The method of claim 14, wherein the treating the substrate is a process of replacing the liquid on the substrate with the organic solvent.

16. The method of claim 15, wherein the liquid on the substrate is pure water.
